(19) United States
(12) Patent Application Publication
(10) Pub. No.: US 2025/0176130 A1
(43) Pub. Date: May 29, 2025

(54) HEAT SINK

(71) Applicant: FURUKAWA ELECTRIC CO., LTD., Tokyo (JP)

(72) Inventors: Shuta HIKICHI, Tokyo (JP); Hiroshi SAKAI, Tokyo (JP); Masahiro MEGURO, Tokyo (JP); Kenya KAWABATA, Tokyo (JP)

(73) Assignee: FURUKAWA ELECTRIC CO., LTD., Tokyo (JP)

(21) Appl. No.: 19/037,001

(22) Filed: Jan. 24, 2025

Related U.S. Application Data
(63) Continuation of application No. PCT/JP2023/027108, filed on Jul. 25, 2023.

(30) Foreign Application Priority Data
Jul. 26, 2022 (JP) 2022-118985

(51) Int. Cl. H05K 7/20

(52) U.S. Cl. CPC H05K 7/20163; H05K 7/20336

(57) ABSTRACT

A heat sink that can reduce pressure loss received by cooling air when the cooling air flows through fins while being excellent in heat exchanging performance of the fins is provided. The heat sink having a heat receiving portion configured to be thermally connected to a heat-generating element, a flat plate-like first radiating fin that is thermally connected to the heat receiving portion, and has a first main front surface, and a flat plate-like second radiating fin that is thermally connected to the heat receiving portion, and has a second main front surface, the second radiating fin having an area of the second main front surface smaller than an area of the first main front surface, wherein the second radiating fin is disposed at a position where the second main front surface overlaps the first main front surface in plan view, between a plurality of the first radiating fins.

### CROSS REFERENCE TO RELATED APPLICATIONS

The present application is a continuation application of International Patent Application No. PCT/JP2023/027108 filed on Jul. 25, 2023, which claims the benefit of Japanese Patent Application No. 2022-118985, filed on Jul. 26, 2022. The contents of these applications are incorporated herein by reference in their entirety.

### BACKGROUND

### Technical Field

The present disclosure relates to a heat sink that cools a heat-generating element

by forced air cooling, and particularly to a heat sink that reduces pressure loss of cooling air while having excellent cooling characteristics.

### Background

Many components including heat-generating elements such as electronic components are being installed in electronic devices at high densities due to enhancement of functionality of the electronic devices in recent years. Heat generation amounts of the heat-generating elements such as electronic components are increasing due to enhancement of functionality of the electronic devices. A heat sink may be used as a unit configured to cool heat-generating elements, such as, electronic components.

A heat sink typically has a base plate thermally connected to a heat-generating element that is a cooling target, and a plurality of radiating fins thermally connected to the base plate, and cools the heat-generating element by supplying cooling air to the radiating fins. Heat sinks are typically required to have excellent cooling characteristics, and hence a heat sink of a structure provided with radiating fins and heat pipes are often used.

As the heat sink of the structure provided with radiating fins and heat pipes, a heat sink as follows has been proposed. The heat sink includes a plurality of extrusion molded materials each having a base plate, and fins protruding from the base plate, and arranged in a width direction orthogonal to an extruding direction and bonded to each other, wherein the plurality of extrusion molded materials each have a plurality of the fins, and a through-hole that is formed so that a heat pipe is fittable in the through-hole and extends in the extruding direction, in the base plate as taught in International Publication No. WO 2019/053791 (2019/053791). In 2019/053791, as a result of local temperature rise in the radiating fins being suppressed by distributing and equalizing the heat load on the respective radiating fins by the heat transporting function of the heat pipes, the heat dissipation characteristics of the radiating fins are improved, and cooling characteristics of the heat sink is improved. Additionally, in the heat sink of 2019/053791, the fin pitches of the plurality of radiating fins are substantially the same.

Meanwhile, to improve the cooling characteristics of the heat sink, it is necessary not only to improve the heat dissipation characteristics of the radiating fins, but also to sufficiently exhibit heat exchanging performance of the radiating fins by the cooling air supplied to the heat sink by being smoothly supplied over the entire radiating fins. To accomplish this, it is necessary to reduce pressure loss received by the cooling air when the cooling air flows through the radiating fins.

In the heat sink of 2019/053791 in which the fin pitches of the plurality of radiating fins are substantially the same, the pressure loss received by the cooling air when the cooling air flows through the radiating fins can be reduced by increasing each of the fin pitches of the plurality of radiating fins that are parallelly disposed. However, when each of the fin pitches among the plurality of radiating fins is increased, the number of radiating fins installed is limited, and hence the heat dissipation characteristics of the radiating fins cannot be improved. Meanwhile, when the number of radiating fins installed is increased to improve the heat dissipation characteristics of the radiating fins, the pressure loss received by the cooling air when the cooling air flows through the radiating fins increases, and the heat exchanging performance of the radiating fins degrades to an unsatisfactory level.

### SUMMARY

The present disclosure is related to a heat sink that reduces pressure loss received by cooling air when the cooling air flows through radiating fins while being excellent in heat exchanging performance of the radiating fins.

A configuration of the present disclosure is as follows.

A heat sink including
a heat receiving portion configured to be thermally connected to a heat-generating element,
a flat plate-like first radiating fin that is thermally connected to the heat receiving portion, and has a first main front surface, and
a flat plate-like second radiating fin that is thermally connected to the heat receiving portion, and has a second main front surface, the second radiating fin having an area of the second main front surface that is smaller than an area of the first main front surface,
wherein the second radiating fin is disposed at a position where the second main front surface overlaps the first main front surface in plan view, between a plurality of the first radiating fins.

The heat sink wherein the entire second main front surface of the second radiating fin is disposed at a position that overlaps the first main front surfaces of the plurality of the first radiating fins in plan view.

The heat sink wherein the heat receiving portion is a flat plate-like base plate, and the first radiating fin and the second radiating fin are parallelly disposed at a predetermined interval in a perpendicular direction to a front surface of the base plate.

The heat sink wherein the first radiating fin and the second radiating fin are thermally connected to the heat receiving portion via a thermally conductive member.

The heat sink wherein the first main front surface has a first through-hole formed in a thickness direction of the first main front surface, the second main front surface has a second through-hole formed in a thickness direction of the second main front surface, and the thermally conductive member is inserted into the first through-hole and the second through-hole.

The heat sink wherein the thermally conductive member is a heat pipe or a vapor chamber.

The heat sink wherein the heat receiving portion is an evaporation portion of a heat pipe, a condensation portion of the heat pipe is provided via a heat insulating portion of the heat pipe continuous with the evaporation portion, and the first radiating fin and the second radiating fin are thermally connected to the condensation portion.

The heat sink wherein a plurality of the heat pipes is provided, and a number of the heat pipes to each of which the first radiating fin and the second radiating fin are thermally connected is larger than a number of the heat pipes to each of which only the first radiating fin is thermally connected.

The heat sink comprising a heat dissipation unit in which one radiating fin group where the first radiating fin and the second radiating fin are parallelly disposed, and another radiating fin group that is adjacent to the one radiating fin group, with the first radiating fin and the second radiating fin being parallelly disposed, are stacked, and the condensation portion of the heat pipe is inserted between the one radiating fin group and the other radiating fin group.

The heat sink including a first protrusion piece protruding in a thickness direction of the first main front surface, in at least a partial region of a peripheral portion of the first main front surface, and a second protrusion piece protruding in a thickness direction of the second main front surface, in at least a partial region of a peripheral portion of the second main front surface, wherein as a result of the first protrusion piece and the second protrusion piece being joined, the first radiating fin and the second radiating fin are joined and integrated.

The heat sink wherein a fin pitch between the plurality of the first radiating fins is an integer multiple of a fin pitch between the first radiating fin and the second radiating fin.

The heat sink wherein the second radiating fin is disposed at a position that overlaps the heat-generating element in plan view.

The heat sink further including a flat plate-like third radiating fin having a third main front surface, wherein an area of the third main front surface is smaller than an area of the second main front surface of the second radiating fin.

The heat sink wherein the third radiating fin is disposed at a position where the third main front surface overlaps the first main front surface in plan view, between the plurality of the first radiating fins.

The heat sink wherein the entire third main front surface of the third radiating fin is disposed at a position that overlaps the first main front surface of the first radiating fin and the second main front surface of the second radiating fin in plan view.

The heat sink wherein the second radiating fin and the third radiating fin are disposed at a position that overlaps the heat-generating element in plan view.

The heat sink wherein a blower fan for supplying cooling air to the first radiating fin and the second radiating fin is not integrated.

The term “plan view” in the above-described aspects means a state where the heat sink is viewed from a direction that faces the main front surfaces of the radiating fins each having a flat plate-like shape. The flat plate-like first radiating fin has the first main front surface as the main front surface contributing to heat dissipation, the flat plate-like second radiating fin has the second main front surface as the main front surface contributing to heat dissipation, and the flat plate-like third radiating fin has the third main front surface as the main front surface contributing to heat dissipation.

In an aspect of the heat sink of the present disclosure, the heat dissipation unit formed by the radiating fin group including the plurality of radiating fins has the first radiating fin and the second radiating fin, and the area of the second main front surface of the second radiating fin is smaller than the area of the first main front surface of the first radiating fin. The second radiating fin is disposed between the plurality of the first radiating fins, in the state where the second main front surface overlaps the first main front surfaces in plan view. From the above, in the aspect of the heat sink of the present disclosure, the heat dissipation unit has the section where the second radiating fin exists, and the section where the second radiating fin does not exist, and of the heat dissipation unit, in the section where the second radiating fin is disposed, the fin pitch of the radiating fins is narrow, whereas in the section where the second radiating fin is not disposed, the fin pitch of the radiating fins is wide. Therefore, according to the aspect of the heat sink of the present disclosure, of the heat dissipation unit, in the section where the second radiating fin is disposed, heat exchanging performance of the radiating fins is excellent, whereas in the section where the second radiating fin is not disposed, pressure loss of the cooling air is reduced, and hence the pressure loss that is received by the cooling air when the cooling air flows through the radiating fins can be reduced, while the heat exchanging performance of the radiating fins is excellent.

According to an aspect of the heat sink of the present disclosure, the entire second main front surface of the second radiating fin is disposed at the position that overlaps the first main front surfaces of the plurality of the first radiating fins in plan view. Therefore, the heat exchanging performance of the radiating fins in the heat dissipation unit is further improved.

According to an aspect of the heat sink of the present disclosure, the heat receiving portion is the flat plate-like base plate, and the first radiating fin and the second radiating fin are disposed parallelly at the predetermined interval in the perpendicular direction to the front surface of the base plate. Therefore, heat of the heat-generating element can be released to the external environment from the heat sink in the installation place of the heat-generating element.

According to an aspect of the heat sink of the present disclosure, the first radiating fin and the second radiating fin are thermally connected to the heat receiving portion via the thermally conductive member. Therefore, the heat from the heat-generating element is reliably conducted from the heat receiving portion to the first radiating fin and the second radiating fin.

According to an aspect of the heat sink of the present disclosure, the first main front surface has the first through-hole formed in the thickness direction of the first main front surface, the second main front surface has the second through-hole formed in the thickness direction of the second main front surface, and the thermally conductive member is inserted into the first through-hole and the second through-hole. Therefore, the thermal connectivity between the thermally conductive member, and the first radiating fin and the second radiating fin is improved, and heat is conducted from the thermally conductive member to the first radiating fin and the second radiating fin more efficiently.

According to an aspect of the heat sink of the present disclosure, the thermally conductive member is a heat pipe or a vapor chamber. Therefore, by the heat transporting function of the heat pipe or the vapor chamber, the heat of the heat-generating element is transported from the heat receiving portion to the first radiating fin and the second radiating fin, and cooling characteristics of the heat sink is further improved.

According to an aspect of the heat sink of the present disclosure, the heat receiving portion is the evaporation portion of the heat pipe, the condensation portion of the heat pipe is provided via the heat insulating portion of the heat pipe continuous with the evaporation portion, and the first radiating fin and the second radiating fin are thermally connected to the condensation portion. Therefore, even when the heat-generating element is installed in a narrow space where the radiating fins cannot be installed, the heat pipe can transport heat from the narrow space to the outside of the narrow space and release the heat in the outside. Therefore, even for the heat-generating element installed in a narrow space, excellent cooling characteristics can be exhibited.

According to an aspect of the heat sink of the present disclosure, a plurality of the heat pipes is provided, the number of the heat pipes to each of which the first radiating fin and the second radiating fin are thermally connected is larger than the number of the heat pipes to each of which only the first radiating fin is thermally connected. Therefore, it is possible to equalize the thermal load on the heat pipes, and the cooling characteristics of the heat sink is further improved.

According to an aspect of the heat sink of the present disclosure, the heat sink includes the first protrusion piece protruding in the thickness direction of the first main front surface, in at least the partial region of the peripheral portion of the first main front surface, and the second protrusion piece protruding in the thickness direction of the second main front surface, in at least the partial region of the peripheral portion of the second main front surface, and as the result of the first protrusion piece and the second protrusion piece being joined, the first radiating fin and the second radiating fin are joined and integrated. Therefore, attaching the first radiating fin and the second radiating fin to the heat sink is facilitated.

According to an aspect of the heat sink of the present disclosure, the second radiating fin is disposed at the position that overlaps the heat-generating element in plan view. Therefore, the heat exchanging performance of the heat dissipation unit of the heat sink is further improved.

According to an aspect of the heat sink of the present disclosure, the heat sink further includes the third radiating fin having the area of the main front surface smaller than the area of the second main front surface of the second radiating fin, and the third radiating fin is disposed at the position where the main front surface of the third radiating fin overlaps the first main front surface in plan view, between the plurality of the first radiating fins. Therefore, the pressure loss received by the cooling air when the cooling air flows through the radiating fins can be further reduced while the heat exchanging performance of the radiating fins is excellent.

### BRIEF DESCRIPTION OF THE DRAWINGS

FIG. 1 is a perspective view of a heat sink according to a first embodiment of the present disclosure.

FIG. 2 is a front view of the heat sink according to the first embodiment of the present disclosure.

FIG. 3 is an explanatory view illustrating an outline of disposition of radiating fins in the heat sink according to the first embodiment of the present disclosure from a front.

FIG. 4 is a plan view of a first radiating fin to be mounted on the heat sink according to the first embodiment of the present disclosure.

FIG. 5 is a front view of the first radiating fin to be mounted on the heat sink according to the first embodiment of the present disclosure.

FIG. 6 is a side view of the first radiating fin to be mounted on the heat sink according to the first embodiment of the present disclosure.

FIG. 7 is a plan view of a second radiating fin to be mounted on the heat sink according to the first embodiment of the present disclosure.

FIG. 8 is a front view of the second radiating fin to be mounted on the heat sink according to the first embodiment of the present disclosure.

FIG. 9 is a side view of the second radiating fin to be mounted on the heat sink according to the first embodiment of the present disclosure.

FIG. 10 is an exploded perspective view of a heat dissipation unit explaining disposition of the first radiating fins and the second radiating fins in the heat sink according to the first embodiment of the present disclosure.

FIG. 11 is an explanatory view illustrating an outline of disposition of radiating fins in a heat sink according to a second embodiment of the present disclosure from a front.

FIG. 12 is an explanatory view illustrating an outline of disposition of radiating fins in a heat sink according to a third embodiment of the present disclosure from a front.

FIG. 13 is an explanatory view illustrating an outline of disposition of radiating fins in a heat sink according to a fourth embodiment of the present disclosure from a front.

FIG. 14 is an explanatory view illustrating an outline of disposition of radiating fins in a heat sink according to a fifth embodiment of the present disclosure from a front.

FIG. 15 is a front view of a heat sink according to a sixth embodiment of the present disclosure.

FIG. 16 is a perspective view of a heat sink according to a seventh embodiment of the present disclosure.

FIG. 17 is a perspective view of a heat sink according to an eighth embodiment of the present disclosure.

FIG. 18 is a front view of the heat sink according to the eighth embodiment of the present disclosure.

FIG. 19 is an explanatory view illustrating an outline of disposition of radiating fins in the heat sink according to the eighth embodiment of the present disclosure from a front.

FIG. 20 is a perspective view of a heat sink according to a ninth embodiment of the present disclosure.

FIG. 21 is a front view of the heat sink according to the ninth embodiment of the present disclosure.

FIG. 22 is an explanatory view illustrating an outline of disposition of radiating fins in the heat sink according to the ninth embodiment of the present disclosure from a front.

### DETAILED DESCRIPTION

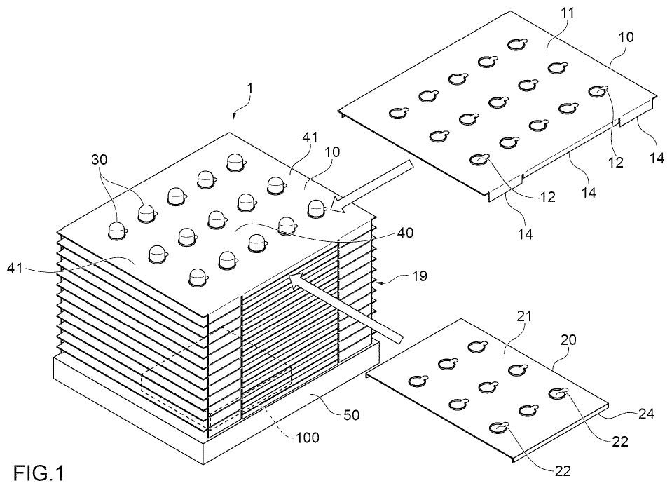

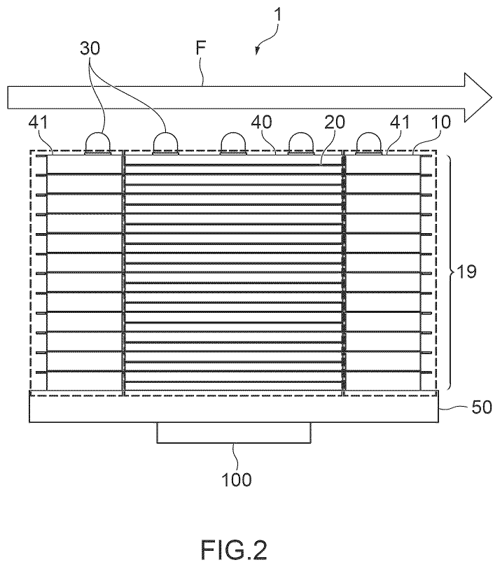

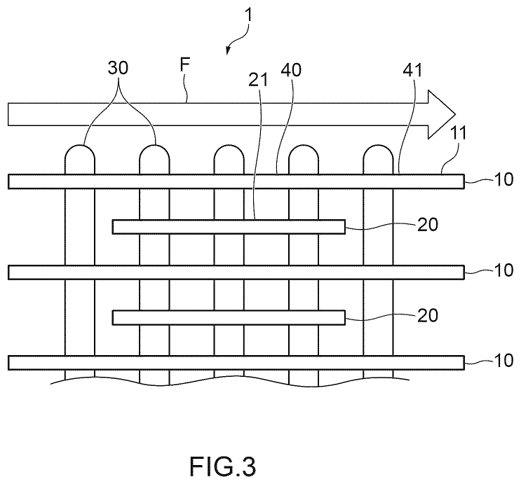

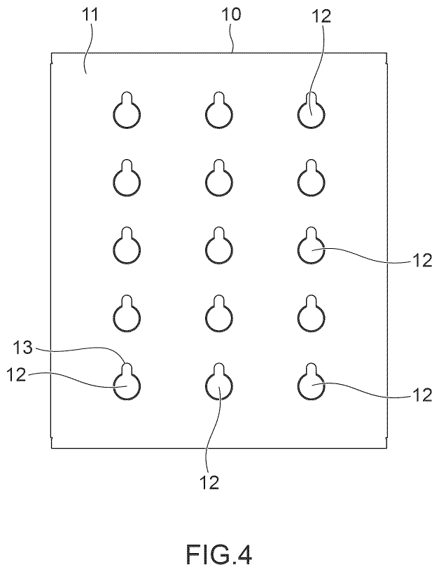

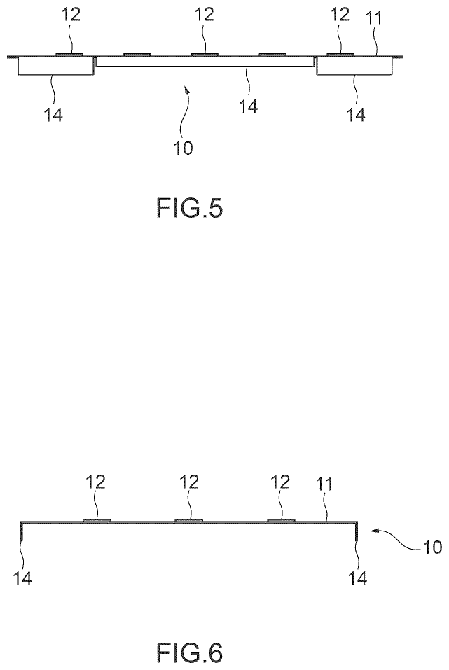

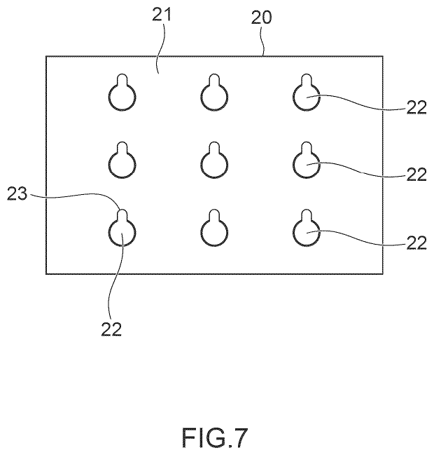

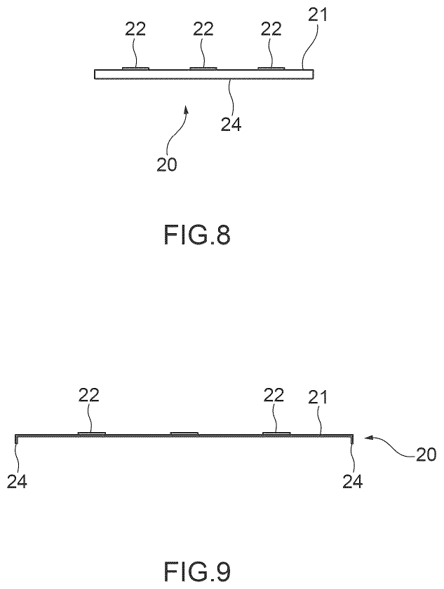

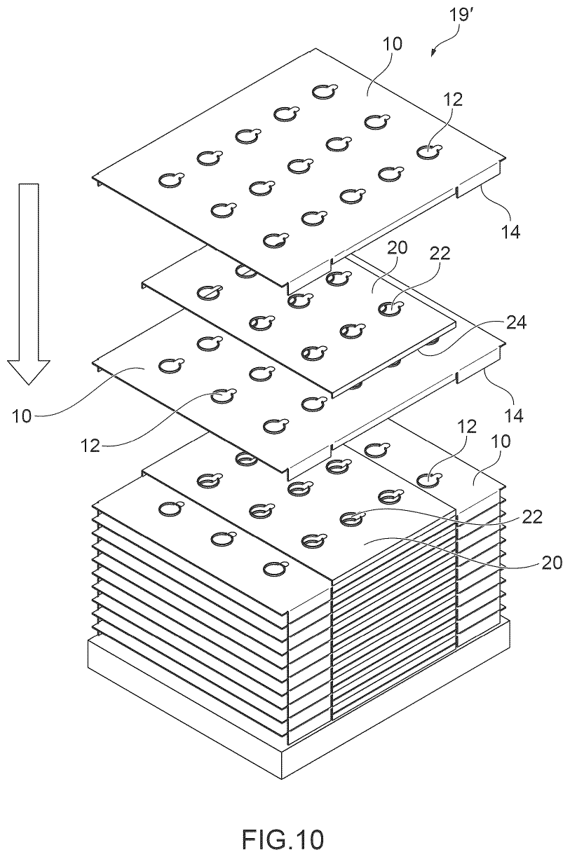

Hereinafter, a heat sink according to a first embodiment of the present disclosure will be described with reference to the accompanying drawings. Note that FIG. 1 is a perspective view of the heat sink according to the first embodiment of the present disclosure. FIG. 2 is a front view of the heat sink according to the first embodiment of the present disclosure. FIG. 3 is an explanatory view illustrating an outline of disposition of radiating fins in the heat sink according to the first embodiment of the present disclosure from a front. FIG. 4 is a plan view of a first radiating fin to be mounted on the heat sink according to the first embodiment of the present disclosure. FIG. 5 is a front view of the first radiating fin to be mounted on the heat sink according to the first embodiment of the present disclosure. FIG. 6 is a side view of the first radiating fin to be mounted on the heat sink according to the first embodiment of the present disclosure. FIG. 7 is a plan view of a second radiating fin to be mounted on the heat sink according to the first embodiment of the present disclosure. FIG. 8 is a front view of the second radiating fin to be mounted on the heat sink according to the first embodiment of the present disclosure. FIG. 9 is a side view of the second radiating fin to be mounted on the heat sink according to the first embodiment of the present disclosure. In each of the explanatory views illustrating the outlines of the disposition of the radiating fins in the heat sinks according to the embodiments of the present disclosure from a front, a first protrusion piece protruded in a thickness direction of a first main front surface, and a second protrusion piece protruding in a thickness direction of a second main front surface that will be described later are not illustrated for convenience of explanation.

As illustrated in FIGS. 1 and 2, a heat sink 1 according to the first embodiment has a flat plate-like base plate 50 that is thermally connected to a heat-generating element 100 on a back surface, and is a heat receiving portion of the heat sink 1, a flat plate-like first radiating fin 10 that is provided on a front surface of the flat plate-like base plate 50, is thermally connected to the flat plate-like base plate 50 that is the heat receiving portion, and has a first main front surface 11, and a flat plate-like second radiating fin 20 that is thermally connected to the flat plate-like base plate 50 that is the heat receiving portion, and has a second main front surface 21. In the first radiating fin 10, the first main front surface 11 that is a main front surface of the first radiating fin 10 mainly has a heat dissipating function. In the second radiating fin 20, the second main front surface 21 that is a main front surface of the second radiating fin 20 mainly has a heat dissipating function.

In the heat sink 1, the heat receiving part is the flat plate-like base plate 50, the first radiating fin 10 and the second radiating fin 20 are parallelly disposed at a predetermined interval in a perpendicular direction to the front surface of the base plate 50. A radiating fin group 19 that is provided on the front surface of the base plate 50 and is formed by a plurality of first radiating fins 10, 10, 10 . . . and a plurality of second radiating fins 20, 20, 20 . . . is a heat dissipation unit of the heat sink 1.

In the heat sink 1, the plurality of first radiating fins 10, 10, 10 . . . is parallelly disposed at predetermined intervals in the perpendicular direction to the front surface of the base plate 50 respectively. All the first radiating fins 10 are parallelly disposed so that the main front surfaces 11 of the first radiating fins 10 are substantially parallel to the front surface of the base plate 50. The intervals of the plurality of first radiating fins 10, 10, 10 . . . are not particularly limited, but in the heat sink 1, the plurality of first radiating fins 10, 10, 10 . . . are arranged at substantially equal intervals. Therefore, the fin pitches of the first radiating fins 10 are substantially equal intervals.

An aspect in which an area of the second main front surface 21 of the second radiating fin 20 is smaller than an area of the first main front surface 11 of the first radiating fin 10 is provided. In other words, an aspect in which the area of the first main front surface 11 of the first radiating fin 10 is larger than the area of the second main front surface 21 of the second radiating fin 20, and heat dissipation characteristics of the first radiating fin 10 is larger than heat dissipation characteristics of the second radiating fin 20 is provided.

As illustrated in FIGS. 1-3, in the heat sink 1, the second radiating fins 20 are each disposed between the plurality of first radiating fins 10, 10, 10 . . . parallelly disposed at the predetermined intervals in the perpendicular direction to the front surface of the base plate 50. In other words, the second radiating fin 20 is inserted between the first radiating fin 10 and the first radiating fin 10. The frequency of inserting the second radiating fin 20 is not particularly limited. However, in the heat sink 1, the first radiating fins 10 and the second radiating fins 20 are alternately disposed along the perpendicular direction to the front surface of the base plate 50.

The plurality of second radiating fins 20, 20, 20 . . . is respectively disposed parallelly at predetermined intervals in the perpendicular direction to the front surface of the base plate 50. All the second radiating fins 20 are parallelly disposed so that the main front surfaces 21 of the second radiating fins 20 are substantially parallel to the front surface of the base plate 50 and the first main front surfaces 11 of the first radiating fins 10. Intervals between the plurality of second radiating fins 20, 20, 20 . . . are not particularly limited, but in the heat sink 1, the plurality of second radiating fins 20, 20, 20 . . . are arranged at substantially equal intervals. Therefore, fin pitches of the second radiating fins 20 are substantially equal intervals.

The second radiating fin 20 is disposed at a position where the second main front surface 21 overlaps the first main front surface 11 of the first radiating fin 10 in plan view. From the above, in the heat sink 1, the radiating fin group 19 that is the heat dissipation unit has a section 40 where the second radiating fin 20 exists, and a section 41 where the second radiating fin 20 does not exist. Of the radiating fin group 19, a fin pitch of the radiating fins in the section 40 where the second radiating fin 20 exists is smaller than a fin pitch of radiating fins in the section 41 where the second radiating fin 20 does not exist. The fin pitch of the radiating fins in the section 41 where the second radiating fin 20 does not exist is the fin pitch of the first radiating fins 10. In the heat sink 1, a center portion of the radiating fin group 19 is the section 40 where the second radiating fin 20 exists, and both end portions of the radiating fin group 19 are the section 41 where the second radiating fin 20 does not exist.

A relationship of the fin pitch between the plurality of first radiating fins 10, 10, 10 . . . and a fin pitch between the first radiating fin 10 and the second radiating fin 20 is not particularly limited. One example is that the fin pitch between the plurality of first radiating fins 10, 10, 10 . . . is an integer multiple (for example, twice) of the fin pitch between the first radiating fin 10 and the second radiating fin 20. In other words, it may be mentioned that in the radiating fin group 19, the fin pitch of the section 41 where the second radiating fin 20 does not exist is an integer multiple (for example, twice) of the fin pitch of the section 40 where the second radiating fin 20 exists.

In the heat sink 1, the entire second main front surface 21 of the second radiating fin 20 is dispose in a position where the entire second main front surface 21 overlaps first main front surfaces 11, 11, 11 . . . of the plurality of first radiating fins 10, 10, 10 . . .

in plan view. Therefore, an external shape of the radiating fin group 19 is formed by the plurality of first radiating fins 10, 10, 10 . . . parallelly disposed in the perpendicular direction to the front surface of the base plate 50.

The plurality of first radiating fins 10, 10, 10 . . . and the plurality of second radiating fins 20, 20, 20 . . . are thermally connected to the base plate 50 that is the heat receiving potion via a thermally conductive member. In other words, the radiating fin group 19 is thermally connected to the base plate 50 that is the heat receiving portion via the thermally conductive member.

In the heat sink 1, as the thermally conductive member, a plurality of heat pipes 30, 30, 30 . . . is used. A heat pipe 30 is a tubular body, and a shape in a longitudinal direction of the heat pipe 30 is not particular limited, and may be a straight-line shape, an L-shape, a U-shape or the like. The heat pipe 30 has a section stretching in the perpendicular direction to the front surface of the base plate 50 from the base plate 50.

Of the heat pipe 30, a section attached to the base plate 50 is a section that functions as an evaporation portion, and stretches in the perpendicular direction to the front surface of the base plate 50, and a section to which the plurality of first radiating fins 10, 10, 10 . . . and the plurality of second radiating fins 20, 20, 20 . . . are thermally connected functions as a condensation portion. The heat pipe 30 is a heat transporting member in which an internal space of the heat pipe 30 is airtight, and further depressurized. The internal space of the heat pipe 30 communicates from the evaporation portion to the condensation portion and is filled with a working fluid. The heat pipe 30 transports heat from the heat-generating element 100 from the evaporation portion to the condensation portion, that is, from the base plate 50 to the plurality of first radiating fins 10, 10, 10 . . . and the plurality of second radiating fins 20, 20, 20 . . . by heat transport characteristics of the heat pipe 30.

A structure that thermally connects the plurality of first radiating fins 10, 10, 10 . . . to the heat pipe 30 is not particularly limited. As shown in FIGS. 1, and 4 to 6, in the heat sink 1, the first main front surface 11 of the first radiating fin 10 has a first through-hole 12 formed in a thickness direction of the first main front surface 11. The first through-hole 12 has a shape corresponding to a shape in a radial direction of the heat pipe 30. The first through-hole 12 is formed in a section of the first main front surface 11 that corresponds to a section of the heat pipe 30 stretching in the perpendicular direction to the front surface of the base plate 50. From the above, a plurality of first through-holes 12 is provided. As a result of the section of the heat pipe 30 stretching in the perpendicular direction to the front surface of the base plate 50 being inserted into the first through-hole 12, the plurality of first radiating fins 10, 10, 10 . . . are thermally connected to the heat pipe 30. A cutout portion 13 formed in the first through-hole 12 is a supply portion for supplying a bonding material such as solder, in the case of using the bonding material such as solder when fixing the first radiating fin 10 to the heat pipe 30.

A structure that thermally connects the plurality of second radiating fins 20, 20, 20 . . . to the heat pipe 30 is not particularly limited. As illustrated in FIGS. 1, and 7 to 9, in the heat sink 1, the second main front surface 21 of the second radiating fin 20 has a second through-hole 22 formed in a thickness direction of the second main front surface 21. The second through-hole 22 has a shape corresponding to the shape in the radial direction of the heat pipe 30. The second through-hole 22 is formed in a section of the second main front surface 21 corresponding to the section of the heat pipe 30 stretching in the perpendicular direction to the front surface of the base plate 50. From the above, a plurality of the second through-holes 22 is provided. As a result of the section of the heat pipe 30 stretching in the perpendicular direction to the front surface of the base plate 50 being inserted into the second through-hole 22, the plurality of second radiating fins 20, 20, 20 . . . is thermally connected to the heat pipe 30. From the above, the section of the heat pipe 30 stretching in the perpendicular direction to the front surface of the base plate 50 is inserted into the first through-hole 12 and the second through-hole 22. A cutout portion 23 formed in the second through-hole 22 is a supply portion for supplying a bonding material such as solder in the case of using the bonding material such as solder when fixing the second radiating fin 20 to the heat pipe 30.

In the radiating fin group 19 of the heat sink 1, the plurality of first radiating fins 10, 10, 10 . . . and the plurality of second radiating fins 20, 20, 20 . . . that are parallelly disposed in the perpendicular direction to the front surface of the base plate 50 are joined and integrated. From the above, the entire radiating fin group 19 has an integrated structure.

As illustrated in FIGS. 1, 5, and 6, the first radiating fin 10 has a first protrusion piece 14 protruding in the thickness direction of the first main front surface 11, in at least a partial region of a peripheral portion of the first main front surface 11. The first radiating fin 10 has the first protrusion piece 14 at a peripheral portion substantially parallel to a flow direction of the cooling air, of the peripheral portion of the first main front surface 11. A protrusion dimension of the first protrusion piece 14 is a dimension corresponding to a fin pitch from another radiating fin adjacent in a protruding direction of the first protrusion piece 14. In the heat sink 1, in a region corresponding to the section 40 where the second radiating fin 20 exists, the protrusion dimension of the first protrusion piece 14 is a dimension corresponding to a fin pitch between the first radiating fin 10 and the second radiating fin 20. Meanwhile, in a region corresponding to the section 41 where the second radiating fin 20 does not exist, the protrusion dimension of the first protrusion piece 14 is a dimension corresponding to the fin pitch between the first radiating fin 10 and the first radiating fin 10.

As illustrated in FIGS. 1, 8, and 9, the second radiating fin 20 has a second protrusion piece 24 protruded in the thickness direction of the second main front surface 21, in at least a partial region of a peripheral portion of the second main front surface 21. The second radiating fin 20 has the second protrusion piece 24 at a peripheral portion substantially parallel to the flow direction of the cooling air, of the peripheral portion of the second main front surface 21. A protrusion dimension of the second protrusion piece 24 is a dimension corresponding to a fin pitch from another radiating fin adjacent in a protruding direction of the second protrusion piece 24. In the heat sink 1, the protruding dimension of the second protrusion piece 24 is a dimension corresponding to the fin pitch between the first radiating fin 10 and the second radiating fin 20.

As a result of the first protrusion piece 14 of the first radiating fin 10 being joined to the other radiating fin (in the heat sink 1, the first radiating fin 10 and/or the second radiating fin 20) adjacent in the protruding direction of the first protrusion piece 14, and the protrusion piece 24 of the second radiating fin 20 being joined to the other radiating fin (in the heat sink 1, the first radiating fin 10) adjacent in the protruding direction of the second protrusion piece 24, the entire radiating fin group 19 is integrated while obtaining the predetermined fin pitches. An example of a joining method using the first protrusion piece 14 and the second protrusion piece 24 includes crimping and joining the first protrusion piece 14 and the second protrusion piece 24.

As a position to which the heat-generating element 100 is thermally connected, of the base plate 50, in the heat sink 1, thermally connecting the heat-generating element 100 so that the second radiating fins 20 are disposed at a position overlapping the heat-generating element 100 in plan view is cited. In other words, thermally connecting the heat-generating element 100 to the position overlapping the section 40 where the second radiating fins 20 of the radiating fin group 19 exits in plan view, is cited.

As illustrated in FIGS. 2 and 3, in the heat sink 1, cooling air F is supplied to the radiating fin group 19 along an extending direction of the first main front surface 11 of the first radiating fin 10 and an extending direction of the second main front surface 21 of the second radiating fin 20. In other words, the cooling air F is supplied to the radiating fin group 19 along an extending direction of the front surface of the base plate 50. In the heat sink 1, a blower fan (not illustrated) for supplying the cooling air F to the first radiating fins 10 and the second radiating fins 20 is not integrated with the heat sink 1. In the heat sink 1, in the flow direction of the cooling air F, a center portion of the radiating fin group 19 is the section 40 where the second radiating fins 20 exist, and both end portions of the radiating fin group 19 are the section 41 where the second radiating fins 20 do not exist.

Materials of the first radiating fin 10 and the second radiating fin 20 are not particularly limited, and for example, metal such as copper, copper alloy, aluminum, aluminum alloy, and stainless steel can be used. A material of the base plate 50 is not particularly limited, and for example, metal such as copper, copper alloy, aluminum, aluminum alloy, and stainless steel can be used. A material of a container used for the heat pipe 30 is not particularly limited, and for example, metal such as copper, copper alloy, aluminum, aluminum alloy, titanium, titanium alloy, and stainless steel can be used. The working fluid to be filled in the container of the heat pipe 30 is appropriately selectable according to adaptability with the material of the container, and, for example, water, fluorocarbons, cyclopentane, ethylene glycol, mixtures of these substances, and the like can be used.

Next, a production method of the radiating fin group 19 of the heat sink 1 will be described. FIG. 10 is an exploded perspective view of the heat dissipation unit explaining disposition of the first radiating fins and the second radiating fins in the heat sink according to the first embodiment of the present disclosure.

As illustrated in FIG. 10, the first radiating fins 10 and the second radiating fins 20 are stacked so that the second radiating fins 20 each having the second through-hole 22 and the second protrusion piece 24 are each disposed between a plurality of the first radiating fins 10 each having the first through-hole 12 and the first protrusion piece 14, and a radiating fin stacked structure 19′ including the plurality of first radiating fins 10, 10, 10 . . . and the plurality of second radiating fins 20, 20, 20 . . . is formed. In the heat sink 1, the first radiating fins 10 and the second radiating fins 20 are alternately stacked. At this time, the radiating fin stacked structure 19′ is formed so that the first through-hole 12 and the second through-hole 22 are overlapped in plan view, and the first protrusion piece 14 and the second protrusion piece 24 are positioned on a same plane.

Thereafter, by crimping the first protrusion piece 14 of the first radiating fin 10 and the second protrusion piece 24 of the second radiating fin 20, the plurality of first radiating fins 10, 10, 10 . . . and the plurality of second radiating fins 20, 20, 20 . . . that form the radiating fin stacked structure 19′ are joined, and the radiating fin group 19 having a structure in which all of the radiating fins are integrated can be produced.

By inserting the heat pipes 30 (sections of the heat pipes 30 stretching in the perpendicular direction to the front surface of the base plate 50) attached to the base plate 50 into the first through-holes 12 and the second through-holes 22 of the radiating fin group 19 produced as described above, the heat sink 1 can be manufactured.

Next, a mechanism by which the heat sink 1 according to the first embodiment cools the heat-generating element 100 that is the cooling target will be described. Heat from the heat-generating element 100 is transferred to the base plate 50 thermally connected to the heat-generating element 100. The heat transferred to the base plate 50 is transferred to the evaporation portion of the heat pipe 30 thermally connected to the base plate 50. When the heat is transferred from the base plate 50 to the evaporation portion of the heat pipe 30, a heat transport system of the heat pipe 30 operates, and the heat absorbed by the evaporation portion of the heat pipe 30 is transported to the condensation portion from the evaporation portion of the heat pipe 30. The heat transported to the condensation portion of the heat pipe 30 is transferred to the first radiating fin 10 and the second radiating fin 20 that are receiving flow of the cooling air F, and are thermally connected to the condensation portion of the heat pipe 30, and further released to an external environment of the heat sink 1 from the first radiating fin 10 and the second radiating fin 20.

In the heat sink 1, of the radiating fin group 19 that is the heat dissipation unit, in the section 40 where the second radiating fins 20 exist, close to the heat-generating element 100, a number of radiating fins installed is large, the fin pitches are small, and hence heat exchanging performance of the radiating fin group 19 is excellent. Meanwhile, of the radiating fin group 19, in the section 41 where the second radiating fins 20 do not exist, relatively far from the heat-generating element 100, the fin pitch is large, and hence pressure loss of the cooing air F is reduced. Therefore, in the heat sink 1, the pressure loss received by the cooling air F when the cooling air F flows through the radiating fin group 19 can be reduced while the heat exchanging performance of the radiating fin group 19 is excellent, and hence excellent cooling characteristics can be exhibited. In the heat sink 1, in terms of the region where the fin pitches are small, of the radiating fin group 19 being limited to a part of the radiating fin group 19, the pressure loss of the cooling air F can also be reduced. In the heat sink 1, excellent cooling characteristics can also be exhibited, in terms of the wind amount of the cooling air F supplied to the radiating fin group 19 increasing correspondingly to being able to reduce the pressure loss of the cooling air F.

In the heat sink 1, the entire second main front surface 21 of the second radiating fin 20 is disposed at the position that overlaps the first main front surfaces 11, 11, 11 . . . of the plurality of first radiating fins 10, 10, 10 . . . in plan view, and hence the heat exchanging performance of the radiating fins in the radiating fin group 19 that is the heat dissipation unit is further improved.

In the heat sink 1, as a result of the heat receiving portion of the heat sink 1 being the base plate 50, and the first radiating fins 10 and the second radiating fins 20 being parallelly disposed in the perpendicular direction to the front surface of the base plate 50, the heat of the heat-generating element 100 is released in the height direction of the heat-generating element 100, and hence the heat of the heat-generating element 100 can be released to the external environment from the heat sink 1 in the installation place of the heat-generating element 100.

In the heat sink 1, the first radiating fins 10 and the second radiating fins 20 are thermally connected to the base plate 50 via the heat pipes 30. Therefore, the heat of the heat-generating element 100 is positively transported from the base plate 50 to the first radiating fins 10 and the second radiating fins 20 by the heat transporting function of the heat pipes 30, and the cooling characteristics of the heat sink 1 are further improved.

In the heat sink 1, the first main front surface 11 of the first radiating fin 10 has the first through-hole 12, the second main front surface 21 of the second radiating fin 20 has the second through-hole 22, and the heat pipe 30 is inserted into the first through-hole 12 and the second through-hole 22. Therefore, thermal connectivity between the heat pipe 30 and the first radiating fin 10 and the second radiating fin 20 is improved, and heat is more efficiently conducted from the heat pipe 30 to the first radiating fin 10 and the second radiating fin 20.

The heat sink 1 has the first protrusion piece 14 protruding in the thickness direction of the first main front surface 11, at the peripheral portion of the first main front surface 11 of the first radiating fin 10, and has the second protrusion piece 24 protruding in the thickness direction of the second main front surface 21, at the peripheral portion of the second main front surface 21 of the second radiating fin 20, and the first protrusion piece 14 and the second protrusion piece 24 are joined by crimping or the like. Therefore, the first radiating fin 10 and the second radiating fin 20 are integrated. Therefore, mounting work of the first radiating fins 10 and the second radiating fins 20 to the heat sink 1 is facilitated.

In the heat sink 1, the second radiating fins 20 are disposed at the position that overlaps the heat-generating element 100 in plan view, that is, the fin pitch of the radiating fin group 19 in the position overlapping the heat-generating element 100 in plan view is relatively small, and hence the heat exchanging performance of the radiating fin group 19 that is the heat dissipation unit is further improved.

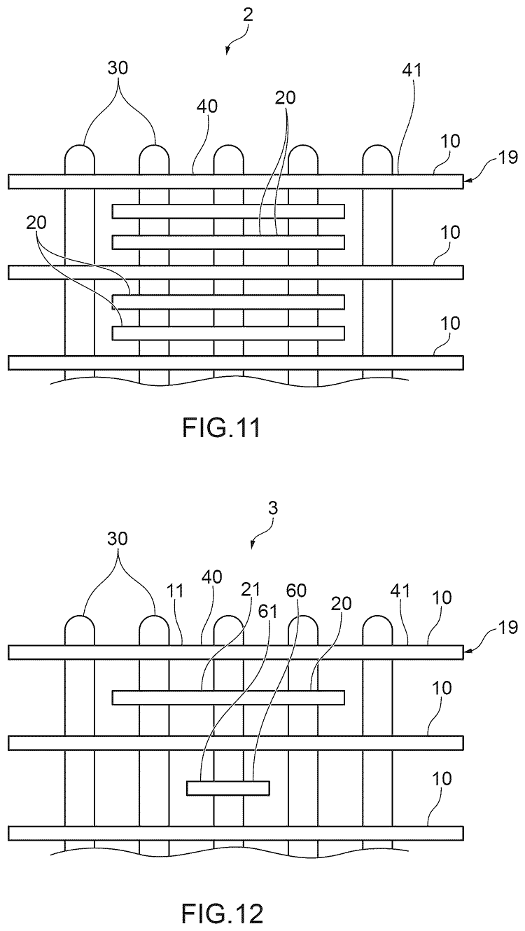

Next, a heat sink according to a second embodiment of the present disclosure will be described with reference to the accompanying drawing. The heat sink according to the second embodiment is in common with the heat sink according to the first embodiment in terms of main components, and hence the same components as those of the heat sink according to the first embodiment are described with use of the same reference characters. FIG. 11 is an explanatory view illustrating an outline of disposition of radiating fins in the heat sink according to the second embodiment of the present disclosure from a front.

In the heat sink 1 according to the first embodiment, the first radiating fins 10 and the second radiating fins 20 are alternately disposed. However, instead of this, as illustrated in FIG. 11, in a heat sink 2 according to the second embodiment, a plurality (two in FIG. 11) of second radiating fins 20 are parallelly disposed at a predetermined interval between adjacent first radiating fins 10. In this manner, in the heat sink of the present disclosure, the number of second radiating fins 20 disposed between the adjacent first radiating fins 10 can be appropriately selected according to a heat generation amount of the heat-generating element that is a cooling target and a degree of pressure loss of cooling air.

Mention is made of, for example, a fin pitch in a section 41 where the second radiating fins 20 do not exist being an integer multiple (for example, three times) of a fin pitch in a section 40 where the second radiating fins 20 do not exist, in a radiating fin group 19 of the heat sink 2.

In the heat sink 2, of the radiating fin group 19, in the section 40 where the second radiating fins 20 exist, close to a heat-generating element, the number of radiating fins installed is also large, the fin pitch is also small, and hence the heat exchanging performance of the radiating fin group 19 is also excellent, whereas in the section 41 where the second radiating fins 20 do not exist, relatively far from the heat-generating element, the fin pitch is also large, and hence pressure loss of the cooling air is also reduced.

Next, a heat sink according to a third embodiment of the present disclosure will be described with reference to the accompanying drawings. The heat sink according to the third embodiment is in common with the heat sinks according to the first and second embodiments in terms of main components, and hence the same components as those of the heat sinks according to the first and second embodiments are described with use of the same reference characters. FIG. 12 is an explanatory view illustrating an outline of disposition of radiating fins in the heat sink according to the third embodiment of the present disclosure from a front.

In the heat sinks 1 and 2 according to the first and second embodiments, the second radiating fin 20 is disposed between the adjacent first radiating fins 10. However, instead of this, as illustrated in FIG. 12, in a heat sink 3 according to the third embodiment further has a flat plate-like third radiating fin 60 having a third main front surface 61, in addition to first radiating fins 10 and second radiating fins 20. An aspect in which an area of the third main front surface 61 that is a main front surface of the third radiating fin 60 is smaller than an area of a second main front surface 21 of the second radiating fin 20 is provided.

A radiating fin group 19 of the heat sink 3 has a section where the second radiating fin 20 is disposed between adjacent first radiating fins 10, and a section where the third radiating fin 60 is disposed between adjacent first radiating fins 10. The heat sink 3 has the section where the one second radiating fin 20 is disposed between the adjacent first radiating fins 10 but the third radiating fin 60 is not disposed, and a section where the one third radiating fin 60 is disposed between the adjacent first radiating fins 10 but the second radiating fin 20 is not disposed. From the above, the heat sink 3 has a configuration in which some of the plurality of second radiating fins 20, 20, 20 . . . of the heat sink 1 are replaced with the third radiating fins 60 is provided.

The third radiating fin 60 is disposed at a position where the third main front surface 61 overlaps a first main front surface 11 of the first radiating fin 10 in plan view, between a plurality of adjacent first radiating fins 10. More specifically, the third radiating fin 60 is disposed at a position where the entire third main front surface 61 of the third radiating fin 60 overlaps the first main front surface 11 of the first radiating fin 10 and the second main front surface 21 of the second radiating fin 20 in plan view. In the heat sink 3, the radiating fin group 19 that is the heat dissipation unit has a section 40 where the second radiating fins 20 exist, and a section 41 where the second radiating fins 20 do not exist, and the third radiating fins 60 also exist in the section 40 where the second radiating fins 20 exist.

As above, in the heat sink of the present disclosure, according to a heat generation amount of a heat-generating element that is a cooling target and a degree of pressure loss of cooling air, a section where the second radiating fin 20 is disposed, and a section where the third radiating fin 60 smaller than an area of the second main front surface 21 of the second radiating fin 20 is disposed may be formed, between the adjacent first radiating fins 10. The heat sink 3 has a configuration in which some of the plurality of second radiating fins 20, 20, 20 . . . in the heat sink 1 are replaced with the third radiating fins 60, and hence pressure loss of the cooling air in section 40 where the second radiating fins 20 exist can also be suppressed. The number of third radiating fins 60 installed in the radiating fin group 19 may be one or more.

In the heat sink 3, for example, in a position that overlaps the heat-generating element in plan view, the second radiating fins 20 and the third radiating fins 60 are disposed.

Since in the heat sink 3, of the radiating fin group 19, in the section 40 where the second radiating fins 20 exist, close to the heat-generating element, the number of radiating fins installed is also large, the fin pitch is also small, and hence the heat exchanging performance of the radiating fin group 19 is also excellent, whereas in the section 41 where the second radiating fins 20 do not exist, relatively far from the heat-generating element, the fin pitch is also relatively large, and hence the pressure loss of the cooling air is also reduced. In the heat sink 3, the third main front surface 61 of the third radiating fin 60 is disposed at the position that overlaps the first main front surface 11 in plan view, and hence the pressure loss received by the cooling air when the cooling air flows through the radiating fin group 19 can be further reduced, while the heat exchanging performance of the radiating fin group 19 is excellent.

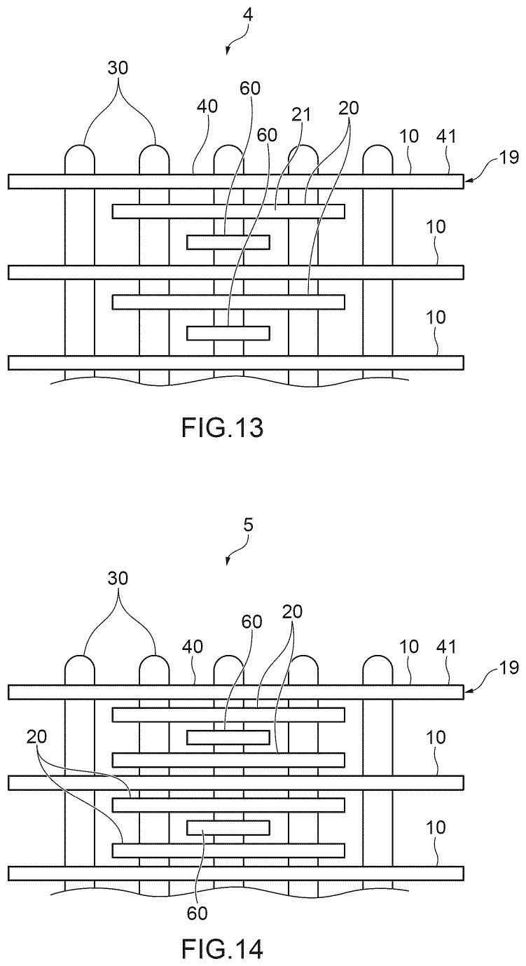

Next, a heat sink according to a fourth embodiment of the present disclosure will be described with reference to the accompanying drawings. The heat sink according to the fourth embodiment is in common with the heat sinks according to the first to third embodiments in terms of main components, and hence the same components as those of the heat sinks according to the first to third embodiments are described with use of the same reference characters. FIG. 13 is an explanatory view illustrating an outline of disposition of radiating fins in the heat sink according to the fourth embodiment of the present disclosure from a front.

In the heat sink 3 according to the third embodiment, the radiating fin group 19 has the section where between the adjacent first radiating fins 10, the second radiating fin 20 is disposed but the third radiating fin 60 is not disposed, and the section where between the adjacent first radiating fins 10, the third radiating fin 60 is disposed but the second radiating fin 20 is not disposed. However, instead of this, as illustrated in FIG. 13, in a heat sink 4 according to the fourth embodiment, between adjacent first radiating fins 10, a second radiating fin 20 and a third radiating fin 60 are disposed. More specifically, between the adjacent first radiating fins 10, the one second radiating fin 20 and one third radiating fin 60 are disposed. In the heat sink 4, the third radiating fin 60 also exists in a section 40 where the second radiating fin 20 exists.

As above, the heat sink of the present disclosure may have a configuration in which the second radiating fin 20 and the third radiating fin 60 having a smaller main front surface than an area of a second main front surface 21 of the second radiating fin 20 are disposed, between the adjacent first radiating fins 10, according to a heat generation amount of a heat-generating element that is a cooling target and a degree of pressure loss of cooling air. The heat sink 4 has a configuration in which some of a plurality of second radiating fins 20, 20, 20 . . . of the heat sink 2 are replaced with the third radiating fins 60, and hence pressure loss of the cooling air in the section 40 where the second radiating fins 20 exists can also be suppressed.

In the heat sink 4, the second radiating fin 20 and the third radiating fin 60 are disposed at a position that overlaps the heat-generating element in plan view, for example.

Since in the heat sink 4, of the radiating fin group 19, in the section 40 where the second radiating fins 20 exist, close to the heat-generating body, the number of radiating fins installed is also large, and the fin pitch is also small, and hence heat exchanging performance of the radiating fin group 19 is also excellent, whereas in a section 41 where the second radiating fins 20 do not exist, relatively far from the heat-generating element, a fin pitch is also relatively large, and hence the pressure loss of the cooling air is also reduced.

Next, a heat sink according to a fifth embodiment of the present disclosure will be described with reference to the accompanying drawings. The heat sink according to the fifth embodiment is in common with the heat sinks according to the first to fourth embodiments in terms of main components, and hence the same components as those of the heat sinks according to the first to fourth embodiments are described with use of the same reference characters. FIG. 14 is an explanatory view illustrating an outline of disposition of radiating fins in the heat sink according to the fifth embodiment of the present disclosure from a front.

In the heat sink 2 according to the second embodiment, the plurality (two) of second radiating fins 20 are parallelly disposed at the predetermined interval between the adjacent first radiating fins 10. However, as illustrated in FIG. 14, in a heat sink 5 according to the fifth embodiment, a plurality (two) of second radiating fins 20 are disposed between adjacent first radiating fins 10, and a third radiating fin 60 is further disposed between the plurality (two) of second radiating fins 20. In the heat sink 5, the one third radiating fin 60 is further disposed between the adjacent second radiating fins 20. In the heat sink 5, the third radiating fin 60 also exists in a section 40 where the second radiating fins 20 exist.

As above, in the heat sink of the present disclosure, the number of second radiating fins 20 and the number of third radiating fins 60 that are inserted between the adjacent first radiating fins 10 can be appropriately selected according to a heat generation amount of the heat-generating element that is a cooling target and a degree of pressure loss of cooling air. In the heat sink 5, pressure loss of cooling air in the section 40 where the second radiating fins 20 exist can also be suppressed.

In the heat sink 5, the second radiating fins 20 and the third radiating fin 60 are also disposed in a position that overlaps the heat-generating element in plan view, for example.

In the heat sink 5, of the radiating fin group 19, in the section 40 where the second radiating fins 20 exist, close to the heat-generating element, the number of radiating fins installed is large, a fin pitch is small, and hence heat exchanging performance of the radiating fin group 19 is excellent, whereas in a section 41 where the second radiating fins 20 do not exist, relatively far from the heat-generating element, a fin pitch is relatively large, and hence pressure loss of the cooling air is reduced.

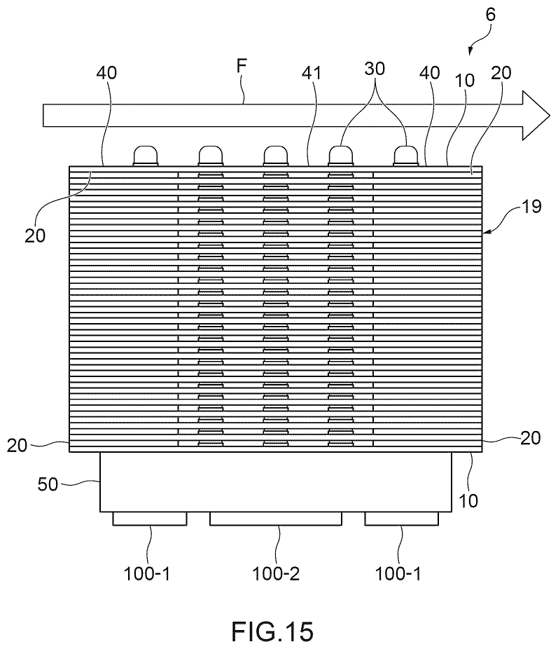

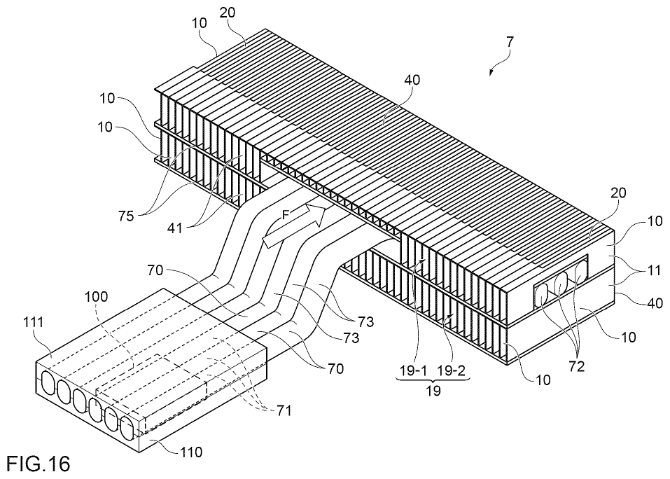

Next, a heat sink according to a sixth embodiment of the present disclosure will be described with reference to the accompanying drawings. The heat sink according to the sixth embodiment is in common with the heat sinks according to the first to fifth embodiments in terms of main components, and hence the same components as those of the heat sinks according to the first to fifth embodiments are described with use of the same reference characters. FIG. 15 is a front view of the heat sink according to the sixth embodiment of the present disclosure.

In each of the above-described embodiments, in the flow direction of the cooling air F, the center portion of the radiating fin group 19 is section 40 where the second radiating fins 20 exist, and both the end portions of the radiating fin group 19 are the section 41 where the second radiating fins 20 do not exist. However, as illustrated in FIG. 15, in a heat sink 6 according to the sixth embodiment, in a flow direction of cooling air F, a center portion of a radiating fin group 19 is a section 41 where second radiating fins 20 do not exist, and both end portions of the radiating fin group 19 are sections 40 where the second radiating fins 20 exist. In other words, in the heat sink 6, the sections 40 where the second radiating fins 20 exist are formed respectively on a windward side end portion and a leeward side end portion of the cooling air F via the center portion of the radiating fin group 19. This corresponds to that in the heat sink 6, of the base plate 50, heat-generating elements 100-1 having large heat generation amounts are thermally connected respectively to both the end portions in the flow direction of the cooling air F, and a heat-generating element 100-2 having a small heat generation amount is thermally connected to the center portion in the flow direction of the cooling air F.

In the heat sink 6, the second radiating fins 20 are each also disposed between a plurality of first radiating fins 10, 10, 10 . . . like the heat sink 1. Meanwhile, in the heat sink 6, the second radiating fins 20 are each inserted between one end portions and other end portions of the first radiating fins 10 in the flow direction of the cooling air F, of the plurality of first radiating fins 10, 10, 10 . . . , and the second radiating fin 20 is not disposed in a center portion of the first radiating fin 10.

As above, in the heat sink of the present disclosure, the section 40 where the second radiating fins 20 exist of the radiating fin group 19 and the section 41 where the second radiating fins 20 do not exist can be appropriately changed so that the section 40 where the second radiating fins 20 exist, of the radiating fin group 19 is positioned on a hot spot of the base plate 50.

In the heat sink 6, of the radiating fin group 19, in the section 40 where the second radiating fins 20 exist, close to the hot spot, the number of radiating fins installed is large, a fin pitch is small, and hence heat exchanging performance of the radiating fin group 19 is excellent, whereas in the section 41 where the second radiating fins 20 do not exist, relatively far from the hot spot, the fin pitch is large, and hence pressure loss of the cooling air is reduced.

Next, a heat sink according to a seventh embodiment of the present disclosure will be described with reference to the accompanying drawings. The heat sink according to the seventh embodiment is in common with the heat sinks according to the first to sixth embodiments in terms of main components, and hence the same components as those of the heat sinks according to the first to sixth embodiments are described with use of the same reference characters. FIG. 16 is a perspective view of the heat sink according to the seventh embodiment of the present disclosure.

In a heat sink 7 according to the seventh embodiment, a heat receiving portion of the heat sink 7 is an evaporation portion of a heat pipe 70 positioned at one end 71 of the heat pipe 70, instead of a base plate. A condensation portion of the heat pipe 70 is provided at another end 72 of the heat pipe 70 via a middle portion (heat insulating portion) 73 of the heat pipe 70 continuous with the evaporation portion positioned at the one end 71 of the heat pipe 70. A radiating fin group 19 having first radiating fins 10 and second radiating fins 20 is thermally connected to the condensation portion positioned at the other end 72 of the heat pipe 70. The heat pipe 70 has the one end 71, the other end 72, and the middle portion 73 connecting the one end 71 and the other end 72, and internal spaces of the one end 71, the middle portion 73 and the other end 72 communicate with one another. The one end 71 of the heat pipe 70 is mounted to a front surface of a heat receiving block 110 and is protected with a cover portion 111. A heat-generating element 100 that is a cooling target is thermally connected to a center portion on a back surface of the heat receiving block 110. The heat pipe 70 is a heat transport member in which an internal space of the heat pipe 70 is airtight and further depressurized. A working fluid is filled in the internal space of the heat pipe 70. The heat pipe 70 transports heat from the heat-generating element 100 from the evaporation portion to the condensation portion by heat transport characteristic of the heat pipe 70.

In the heat sink 7, a plurality of heat pipes 70, 70, 70 . . . is parallelly provided along a radial direction of the heat pipe 70. With respect to each of the heat pipes 70, a bent portion in a longitudinal direction of the heat pipe 70 is formed at the other end 72 thermally connected to the radiating fin group 19. Therefore, each of the plurality of heat pipes 70, 70, 70 . . . has a substantially L-shape. A bent portion of the heat pipe 70 positioned on a right side is a rightward bend, whereas a bent portion of the heat pipe 70 positioned on a left side is a leftward bend. In other words, bending directions of the bent portions of the heat pipe 70 positioned on the right side and the heat pipe 70 positioned on the left side are opposite.

An aspect in which the other ends 72 of all the plurality of heat pipes 70, 70, 70 . . . extend in a substantially parallel direction to a longitudinal direction of the radiating fin group 19 by the bent portions is provided. In the heat sink 7, the other end 72 of the heat pipe 70 reaches an end portion in the longitudinal direction of the radiating fin group 19.

A plurality of first radiating fins 10, 10, 10 . . . is parallelly disposed so that first main front surfaces 11 of the first radiating fins 10 are disposed in a substantially parallel direction to a stretching direction of the one end 71 of the heat pipe 70. A plurality of second radiating fins 20, 20, 20 . . . are parallelly disposed so that second main front surfaces of second radiating fins 20 are disposed in a substantially parallel direction to the stretching direction of the one end 71 of the heat pipe 70. In the radiating fin group 19, the second radiating fin 20 is disposed between a plurality of first radiating fins 10. In the heat sink 7, the first radiating fins 10 and the second radiating fins 20 are alternately disposed for convenience of explanation. In the radiating fin group 19 of the heat sink 7, a section that is positioned windward of cooling air F is a section 41 where the second radiating fins 20 do not exist, and a section positioned leeward of the cooling air F is a section 40 where the second radiating fins 20 exist.

As illustrated in FIG. 16, the heat sink 7 provides an aspect in which the plurality of heat pipes 70, 70, 70 . . . is provided, and the number of heat pipes 70 to which the first radiating fins 10 and the second radiating fins 20 are thermally connected is larger than the number of heat pipes 70 to which only the first radiating fins 10 are thermally connected. In other words, an aspect in which the number of heat pipes 70 that are thermally connected to the section 40 where the second radiating fins 20 exist is larger than the number of heat pipes 70 that are thermally connected to the section 41 where the second radiating fins 20 do not exist is provided. In FIG. 16, for example, of the three heat pipes 70 on the right side, the first radiating fins 10 and the second radiating fins 20 are thermally connected to the second heat pipe 70 and the third heat pipe 70 from the right side, and only the first radiating fins 10 are thermally connected to the first heat pipe 70 from the right side. In the heat pipes 70 to which the first radiating fins 10 and the second radiating fins 20 are thermally connected, the one ends 71 of the heat pipes 70 are thermally connected to the heat-generating element 100 via the heat receiving block 110 in a position close to the heat-generating element 100. Therefore, In the heat pipes 70 to which the first radiating fins 10 and the second radiating fins 20 are thermally connected, thermal load increases. Meanwhile, in the heat pipe 70 to which only the first radiating fins 10 are thermally connected, the one end 71 of the heat pipe 70 is thermally connected to the heat-generating element 100 via the heat receiving block 110 at a position far from the heat-generating element 100. Therefore, in the heat pipe 70 to which only the first radiating fin 10 is thermally connected, thermal load is relatively small.

An external shape of the radiating fin group 19 that is a heat dissipation unit of the heat sink 7 is substantially a rectangular parallelepiped. The radiating fin group 19 has a structure in which one radiating fin group 19-1 having an external shape that is substantially a rectangular parallelepiped, and having the first radiating fins 10 and the second radiating fins 20 alternately disposed parallelly, and another radiating fin group 19-2 that is adjacent to the one radiating fin group 19-1, has an external shape that is substantially a rectangular parallelepiped, and has the first radiating fins 10 and the second radiating fin 20 alternately disposed parallelly are stacked. The one radiating fin group 19-1 and the other radiating fin group 19-2 each have a structure in which the plurality of first radiating fins 10, 10, 10 . . . and the plurality of second radiating fins 20, 20, 20 . . . that are mounted on a flat plate-like substrate 75 are parallelly disposed in a substantially parallel direction to the longitudinal direction of the radiating fin group 19.

The other ends 72 that are the condensation portions of the heat pipes 70 are inserted between the one radiating fin group 19-1 and the other radiating fin group 19-2. As a result of the other ends 72 of the heat pipes 70 being disposed between the one radiating fin group 19-1 and the other radiating fin group 19-2, the radiating fin group 19 and the heat pipes 70 are thermally connected.

In the heat sink 7, of the radiating fin group 19, in the section 40 where the heat pipes 70 having large thermal load are thermally connected, and the second radiating fins 20 exist, the number of radiating fins installed is large, fin pitches are small, and hence heat exchanging performance of the radiating fin group 19 is excellent, whereas in the section 41 where the heat pipes 70 having small thermal load are thermally connected, and the second radiating fins 20 do not exist, fin pitches are large, and hence pressure loss of the cooling air F is reduced. Therefore, in the heat sink 7, the pressure loss received by the cooling air F when the cooling air F flows through the radiating fin group 19 can also be reduced while the heat exchanging performance of the radiating fin group 19 is excellent, and hence excellent cooling characteristics can also be exhibited.

In the heat sink 7, even when the heat-generating element 100 is installed in a narrow space where the radiating fin group 19 cannot be installed, the heat pipe 70 can transport heat from the narrow space to an outside of the narrow space, and release heat in the outside by a heat exchanging action of the radiating fin group 19. Therefore, excellent cooling characteristics are exhibited for even the heat-generating element 100 installed in the narrow space.

In the heat sink 7, as a result of the number of heat pipes 70 to which the first radiating fins 10 and the second radiating fins 20 are thermally connected being larger than the number of heat pipes 70 to which only the first radiating fins 10 are thermally connected, it becomes possible to equalize the thermal load on the plurality of heat pipes 70, 70, 70 . . . , and cooling characteristics of the heat sink 7 is further improved.

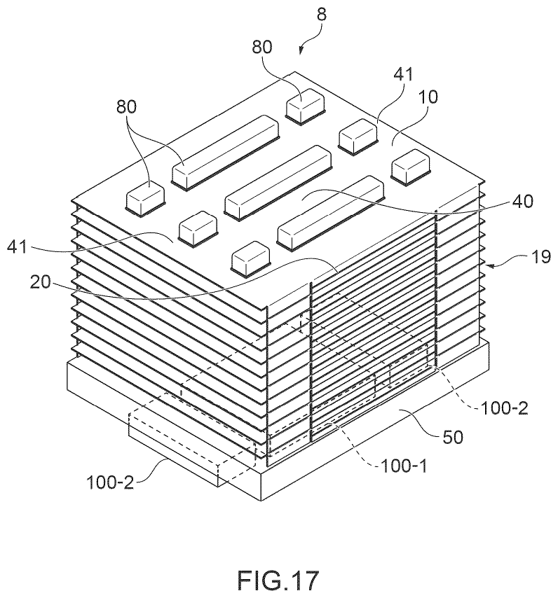

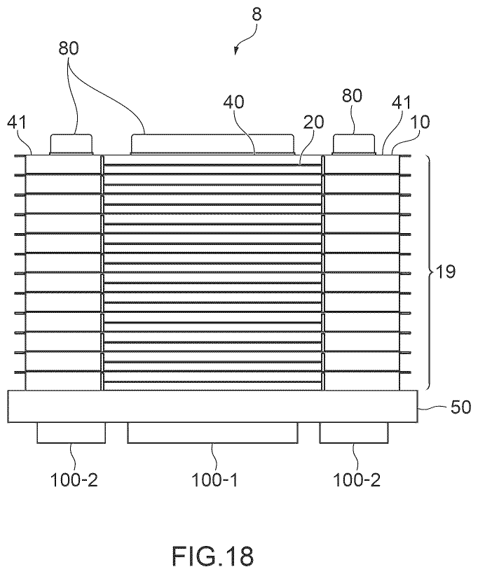

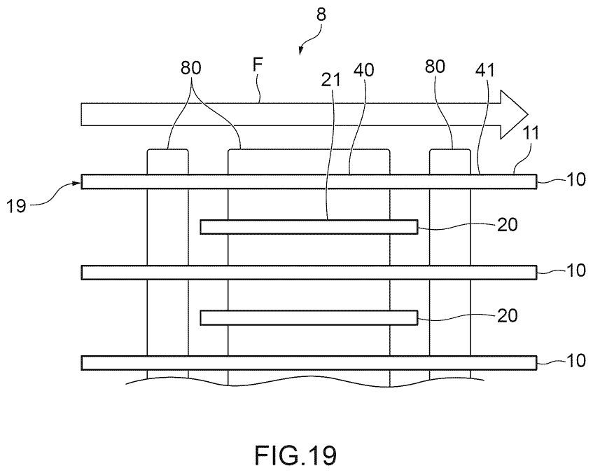

Next, a heat sink according to an eighth embodiment of the present disclosure will be described with reference to the accompanying drawings. The heat sink according to the eighth embodiment is in common with the heat sinks according to the first to seventh embodiments in terms of main components, and hence the same components as those of the heat sinks according to the first to seventh embodiments are described with use of the same reference characters. FIG. 17 is a perspective view of the heat sink according to the eighth embodiment of the present disclosure. FIG. 18 is a front view of the heat sink according to the eighth embodiment of the present disclosure. FIG. 19 is an explanatory view illustrating an outline of disposition of radiating fins in the heat sink according to the eighth embodiment of the present disclosure from a front.

In each of the above-described embodiments, as the thermally conductive member, a plurality of heat pipes 30, 30, 30 . . . that are tubular bodies are used. However, as illustrated in FIGS. 17, 18, and 19, in a heat sink 8 according to the eighth embodiment, as a thermally conductive member, a plurality of vapor chambers 80, 80, 80 . . . each having a planar-surface type shape are used. Specifically, the heat sink 8 provides an aspect in which vapor chambers 80 that are plate-like heat transporting members are used instead of the heat pipes 30 of the heat sink 1 according to the first embodiment.

Of the vapor chambers 80, sections mounted on a base plate 50 function as an evaporation portion, and sections that are sections stretching in a perpendicular direction to a front surface of the base plate 50, with a plurality of first radiating fins 10, 10, 10 . . . and a plurality of radiating fins 20, 20, 20 . . . being thermally connected to the sections function as a condensation portion. The vapor chamber 80 is a heat transporting member in which an internal space of the vapor chamber 80 is airtight, and further depressurized. The internal space of the vapor chamber 80 communicates from the evaporation portion to the condensation portion and is filled with a working fluid. The vapor chamber 80 transports heat from a heat-generating element 100 from the evaporation portion to the condensation portion, that is, from the base plate 50 to the plurality of first radiating fins 10, 10, 10 . . . and the plurality of second radiating fins 20, 20, 20 . . . , by heat transport characteristics of the vapor chamber 80.

A shape of a heat transporting direction of the vapor chamber 80 is not particularly limited, and may be a straight-line shape, an L-shape, a U-shape or the like. The vapor chamber 80 has a section that stretches in a perpendicular direction to the front surface of the base plate 50 from the base plate 50.

In the heat sink 8, a section 40 where the second radiating fins 20 exist is formed at a center portion of a radiating fin group 19, and sections 41 where the second radiating fins 20 do not exist are formed respectively at a windward side end portion and a leeward side end portion of cooling air F via the center portion of the radiating fin group 19, similarly to the heat sink 1. In the heat sink 8, of the base plate 50, to both the end portions in a flow direction of the cooling air F, heat-generating elements 100-2 having low heat generation amounts are thermally connected respectively, and a heat-generating element 100-1 having a high heat generation amount is thermally connected to the center portion in the flow direction of the cooling air F, in response to a position of the second radiating fins 20 in the radiating fin group 19.

In the heat sink 8, of the radiating fin group 19, in the section 40 where the second radiating fins 20 exist, close to the heat-generating element 100-1 having a high heat generation amount, the number of radiating fins installed is large, a fin pitch is small, and hence heat exchanging performance of the radiating fin group 19 is excellent, whereas in the section 41 where the second radiating fins 20 do not exist, relatively far from the heat-generating element 100-1 having a high heat generation amount, a fin pitch is large, and hence pressure loss of the cooling air is reduced. In the heat sink 8, as a result of the first radiating fins 10 and the second radiating fins 20 being thermally connected to the base plate 50 via the vapor chambers 80, heat of the heat-generating element 100 is positively transported from the base plate 50 to the first radiating fins 10 and the second radiating fins 20, by a heat transporting function of the vapor chambers 80, and cooling characteristics of the heat sink 1 is further improved.

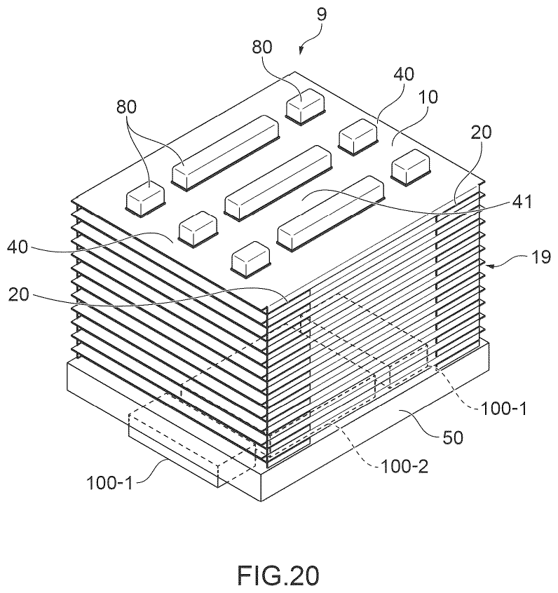

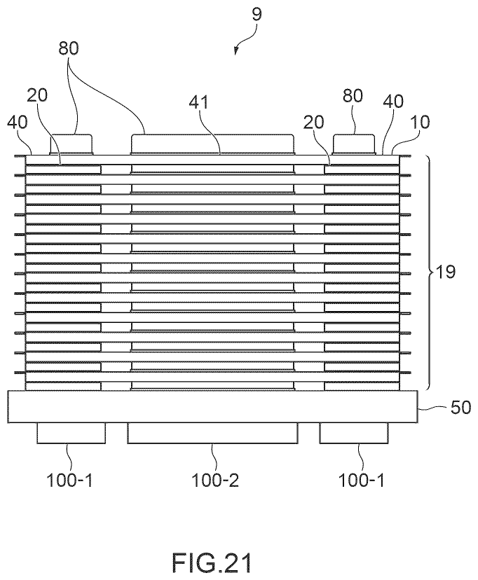

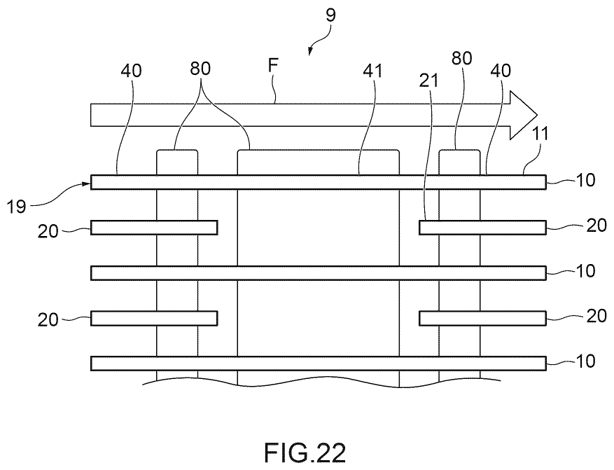

Next, a heat sink according to a ninth embodiment of the present disclosure will be described with reference to the accompanying drawings. The heat sink according to the ninth embodiment is in common with the heat sinks according to the first to eighth embodiments in terms of main components, and hence the same components as those of the heat sinks according to the first to eighth embodiments are described with use of the same reference characters. FIG. 20 is a perspective view of the heat sink according to the ninth embodiment of the present disclosure. FIG. 21 is a front view of the heat sink according to the ninth embodiment of the present disclosure. FIG. 22 is an explanatory view illustrating an outline of disposition of radiating fins in the heat sink according to the ninth embodiment of the present disclosure from a front.

In the first to seventh embodiments, the plurality of heat pipes 30, 30, 30 . . . that are tubular bodies are used as the thermally conductive members. However, as illustrated in FIGS. 20, 21, and 22, in the heat sink 9 according to the ninth embodiment, a plurality of vapor chambers 80, 80, 80 . . . each having a planar-surface type shape are used as thermally conductive members. Specifically, the heat sink 9 provides an aspect in which the vapor chambers 80 that are plate-like heat transporting members are used instead of the heat pipes 30 of the heat sink 6 according to the sixth embodiment.

From the above, in the heat sink 9, in a flow direction of cooling air F, a center portion of a radiating fin group 19 is a section 41 where second radiating fins 20 do not exist, and both end portions of the radiating fin group 19 are sections 40 where the second radiating fins 20 exist. Specifically, in the heat sink 9, the sections 40 where the second radiating fins 20 exist are formed respectively at a windward side end portion and a leeward side end portion of the cooling air F via the center portion of the radiating fin group 19. This corresponds to that in the heat sink 9, of a base plate 50, to both end portions in the flow direction of the cooling air F, heat-generating elements 100-1 having high heat generation amounts are thermally connected respectively, and a heat-generating element 100-2 having a low heat generation amount is thermally connected to the center portion in the flow direction of the cooling air F.

In the heat sink 9, of the radiating fin group 19, in the section 40 where the second radiating fins 20 exist, close to the heat-generating element 100-1 having a high heat generation amount, the number of radiating fins installed is also large, a fin pitch is also small, and hence heat exchanging performance of the radiating fin group 19 is also excellent, whereas in the section 41 where the second radiating fins 20 do not exist, relatively far from the heat-generating element 100-1 having a high heat generation amount, a fin pitch is also large, and hence pressure loss of the cooling air is also reduced. In the heat sink 9, as a result of the first radiating fins 10 and the second radiating fins 20 being also thermally connected to the base plate 50 via the vapor chamber 80, the heat of the heat-generating element 100 is also positively transported from the base plate 50 to the first radiating fins 10 and the second radiating fins 20 by the heat transporting function of the vapor chambers 80, and cooling characteristics of the heat sink 9 are also further improved.

Next, another embodiment of the heat sink of the present disclosure will be described. In the heat sink 7 according to the seventh embodiment described above, the radiating fin group 19 has the first radiating fins 10 and the second radiating fins 20. However, instead of this, the radiating fin group 19 may further have a third radiating fin having a main front surface smaller than an area of a second main front surface 21 of a second radiating fin 20. In the above-described aspect, the third radiating fin may be disposed between adjacent first radiating fins 10, or the third radiating fin may be disposed between adjacent second radiating fins 20.

The heat sink of the present disclosure can also exhibit excellent cooling performance with respect to the heat-generating elements having high heat generation amounts, and therefore is usable in a wide range of fields. For example, the heat sink of the present disclosure has high utility value in the field of cooling electronic components installed in moving objects such as railway vehicles, aircraft, and automobiles, electronic devices, servers and the like.

What is claimed is:

1. A heat sink comprising:
a heat receiving portion configured to be thermally connected to a heat-generating element;
a flat plate-like first radiating fin that is thermally connected to the heat receiving portion, and has a first main front surface; and
a flat plate-like second radiating fin that is thermally connected to the heat receiving portion, and has a second main front surface, the second radiating fin having an area of the second main front surface smaller than an area of the first main front surface,
wherein the second radiating fin is disposed at a position where the second main front surface overlaps the first main front surface, between a plurality of the first radiating fins,
the second radiating fin is disposed at a position that overlaps the heat-generating element,
a radiating fin group has the first radiating fin and the second radiating fin, and
of the radiating fin group, a section where the second radiating fin does not exist is farther from the heat-generating element than a section where the second radiating fin exists.

2. The heat sink according to claim 1, wherein a number of the heat-generating elements configured to be thermally connected to the heat receiving portion is one.

3. The heat sink according to claim 1, wherein the entire second main front surface of the second radiating fin is disposed at a position that overlaps the first main front surfaces of the plurality of the first radiating fins.

4. The heat sink according to claims 1, wherein the heat receiving portion is a flat plate-like base plate, and the first radiating fin and the second radiating fin are parallelly disposed at a predetermined interval in a perpendicular direction to a front surface of the base plate.

5. The heat sink according to claim 1, wherein the first radiating fin and the second radiating fin are thermally connected to the heat receiving portion via a thermally conductive member.

6. The heat sink according to claim 5, wherein the first main front surface has a first through-hole formed in a thickness direction of the first main front surface, the second main front surface has a second through-hole formed in a thickness direction of the second main front surface, and the thermally conductive member is inserted into the first through-hole and the second through-hole.

7. The heat sink according to claim 5, wherein the thermally conductive member is a heat pipe or a vapor chamber.

8. The heat sink according to claim 1, wherein the heat receiving portion is an evaporation portion of a heat pipe, a condensation portion of the heat pipe is provided via a heat insulating portion of the heat pipe continuous with the evaporation portion, and the first radiating fin and the second radiating fin are thermally connected to the condensation portion.

9. The heat sink according to claim 8, wherein a plurality of the heat pipes are provided, and a number of the heat pipes to each of which the first radiating fin and the second radiating fin are thermally connected is larger than a number of the heat pipes to each of which only the first radiating fin is thermally connected.

10. The heat sink according to claim 1, comprising a first protrusion piece protruding in a thickness direction of the first main front surface, in at least a partial region of a peripheral portion of the first main front surface, and a second protrusion piece protruding in a thickness direction of the second main front surface, in at least a partial region of a peripheral portion of the second main front surface, wherein as a result of the first protrusion piece and the second protrusion piece being joined, the first radiating fin and the second radiating fin are joined and integrated.

11. The heat sink according to claim 1, wherein a fin pitch between the plurality of the first radiating fins is an integer multiple of a fin pitch between the first radiating fin and the second radiating fin.

12. The heat sink according to claim 1, further comprising a flat plate-like third radiating fin having a third main front surface, wherein an area of the third main front surface is smaller than an area of the second main front surface of the second radiating fin.

13. The heat sink according to claim 12, wherein the third radiating fin is disposed at a position where the third main front surface overlaps the first main front surface, between the plurality of the first radiating fins.

14. The heat sink according to claim 12, wherein the entire third main front surface of the third radiating fin is disposed at a position that overlaps the first main front surface of the first radiating fin and the second main front surface of the second radiating fin.

15. The heat sink according to claim 12, wherein the second radiating fin and the third radiating fin are disposed at a position that overlaps the heat-generating element.

16. The heat sink according to claim 1, wherein a blower fan for supplying cooling air to the first radiating fin and the second radiating fin is not integrated.

17. The heat sink according to claim 1, wherein the section where the second radiating fin does not exist is disposed at a position that does not overlap the heat-generating element.
